(19) United States
(12) Patent Application Publication
(10) Pub. No.: US 2026/0004974 A1
(43) Pub. Date: Jan. 1, 2026

(54) MULTILAYER CERAMIC CAPACITOR AND CIRCUIT BOARD

(71) Applicant: TAIYO YUDEN CO., LTD., Tokyo (JP)

(72) Inventors: Tomoki INOUE, Tokyo (JP); Yoshinari TAKE, Tokyo (JP); Takeshi SAKASHITA, Tokyo (JP); Yuka NAITO, Tokyo (JP)

(73) Assignee: TAIYO YUDEN CO., LTD., Tokyo (JP)

(21) Appl. No.: 19/252,677

(22) Filed: Jun. 27, 2025

(30) Foreign Application Priority Data
Jul. 1, 2024 (JP) 2024-105949

(51) Int. Cl. H01G 4/232; H01G 4/30; H05K 1/18

(52) U.S. Cl. CPC H01G 4/232; H01G 4/30; H05K 1/181; H05K 2201/10015

(57) ABSTRACT

A multilayer ceramic capacitor includes a cuboid element body having a multilayer unit alternately laminating ceramic layers and internal electrodes composed primarily of metal, a pair of covering portions arranged at both ends of the multilayer unit in the laminating direction and covering surfaces of the multilayer unit, and margin portions covering at least some of the end portions of the ceramic layers and the internal electrodes in the multilayer unit, and connecting the pair of covering portions to each other; and a plurality of terminal electrodes electrically connected to the internal electrodes, and arranged in a spaced-apart manner on a mounting surface, which is one of the surfaces forming the surfaces of the element body, facing the circuit board during circuit board mounting, wherein the plurality of terminal electrodes are arranged in m units in a first direction on the mounting surface and n units in a second direction perpendicular to the first direction (where m is a natural number equal to or greater than 2 and n is a natural number), a region in which the terminal electrodes are not arranged on the mounting surface has a mounting surface side intersection portion in which a first straight line and a second straight line intersect, and a mounting surface side non-intersection portion in which the first straight line and the second straight line do not intersect, when the first straight line is drawn to extend in the first direction without touching any of the terminal electrodes and the second straight line is drawn to extend in the second direction without touching any of the terminal electrodes, and the element body satisfies T1<T2, where T1 is a dimension in the laminating direction of the element body, as measured with reference to a mounting surface side intersection portion, and T2 is a dimension in the laminating direction of the element body, as measured with reference to a mounting surface side non-intersection portion.

### CROSS-REFERENCE TO RELATED APPLICATIONS

This application claims the benefit of Japanese Application No. 2024-105949, filed Jul. 1, 2024, in the Japanese Patent Office. All disclosures of the document named above are incorporated herein by reference.

### BACKGROUND OF THE INVENTION

### 1. Field of the Invention

Aspects of the present invention relate to a multilayer ceramic capacitor and a circuit board.

### 2. Description of the Related Art

A wide variety of ceramic electronic components are used in high-frequency communication systems, such as those for mobile phones. There is demand for smaller and thinner ceramic electronic components, and smaller and thinner multilayer ceramic capacitors are being considered.

Patent Document 1 discloses a thin, damage-resistant multilayer ceramic capacitor, in which via-hole electrodes used to electrically connect internal electrode layers to each other and to electrically connect internal electrode layers to terminal electrodes are formed with a void inside. In the multilayer ceramic capacitor disclosed in Patent Document 1, terminal electrodes are formed on the flat upper surface of the element body.

### PRIOR ART DOCUMENTS

### Patent Documents

Patent Document 1: JP 2020-072263 A

### SUMMARY OF THE INVENTION

### Problem(s) to be Solved by the Invention

A multilayer ceramic capacitor is mounted on a circuit board by soldering terminal electrodes to pads on the circuit board. At this time, the exposed regions of the upper surface of the element body on which the terminal electrodes are not arranged, and thus not covered by the terminal electrodes, contribute little to the bonding strength of the solder due to their flat shape. As a result, when a circuit board with a multilayer ceramic capacitor mounted on it is bent or deformed, stress is concentrated at the interface between the terminal electrodes and the solder, especially at the corners of terminal electrodes with a small area, and delamination occurs at the interface starting from these corners, causing poor contact between the multilayer ceramic capacitor and the circuit board.

It is an object of the present invention to solve this problem by providing a multilayer ceramic capacitor with improved bonding strength to circuit boards, and a circuit board on which this multilayer ceramic capacitor is mounted.

### Means for Solving the Problem

As a result of extensive research conducted to solve the problem described above, the present inventor discovered that the object described above could be achieved by making specific portions of the region in which no terminal electrodes are arranged on the mounting surface of the element body in a multilayer ceramic capacitor, that is, the surface facing the circuit board when the multilayer ceramic capacitor is mounted on the circuit board, recessed relative to the other portions.

A first aspect of the present invention that solves this problem is a multilayer ceramic capacitor comprising: a cuboid element body having a multilayer unit alternately laminating ceramic layers and internal electrodes composed primarily of metal, a pair of covering portions arranged at both ends of the multilayer unit in the laminating direction and covering surfaces of the multilayer unit, and margin portions covering at least some of the end portions of the ceramic layers and the internal electrodes in the multilayer unit, and connecting the pair of covering portions to each other; and a plurality of terminal electrodes electrically connected to the internal electrodes, and arranged in a spaced-apart manner on a mounting surface, which is one of the surfaces forming the surfaces of the element body, facing the circuit board during circuit board mounting, wherein the plurality of terminal electrodes are arranged in m units in a first direction on the mounting surface and n units in a second direction perpendicular to the first direction (where m is a natural number equal to or greater than 2 and n is a natural number), a region in which the terminal electrodes are not arranged on the mounting surface has a mounting surface side intersection portion in which a first straight line and a second straight line intersect, and a mounting surface side non-intersection portion in which the first straight line and the second straight line do not intersect, when the first straight line is drawn to extend in the first direction without touching any of the terminal electrodes and the second straight line is drawn to extend in the second direction without touching any of the terminal electrodes, and the element body satisfies T1<T2, where T1 is a dimension in the laminating direction of the element body, as measured with reference to a mounting surface side intersection portion, and T2 is a dimension in the laminating direction of the element body, as measured with reference to a mounting surface side non-intersection portion.

A second aspect of the present invention that solves this problem is a circuit board carrying the multilayer ceramic capacitor according the first aspect of the present invention.

### Effect of the Invention

The present invention is able to provide a multilayer ceramic capacitor with improved bonding strength to a circuit board, and a circuit board on which this multilayer ceramic capacitor is mounted.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram (perspective view) of the structure of the multilayer ceramic capacitor in a first embodiment of the present invention.

FIG. 2 is a cross-sectional view (LT cross-sectional view) from A-A in FIG. 1.

FIG. 3 is a top view (LW plan view) of FIG. 1.

FIG. 4 is a schematic diagram (LT cross-sectional view) showing the preferred shape of the mounting surface of the multilayer ceramic capacitor in the first embodiment.

FIG. 5 is a schematic diagram (LT plan view) of the structure of the multilayer ceramic capacitor in a second embodiment of the present invention.

FIG. 6 is a schematic diagram (LT plan view) of the structure of the multilayer ceramic capacitor in a third embodiment of the present invention.

FIG. 7 is a schematic diagram (perspective view) of the structure of the multilayer ceramic capacitor in a fourth embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The configuration and effects of the present invention will now be described, including technical ideas, with reference to the accompanying drawings. However, this description includes assumptions about the operating mechanism, and the correctness of these assumptions does not limit the scope of the present invention.

### Multilayer Ceramic Capacitor

### First Embodiment

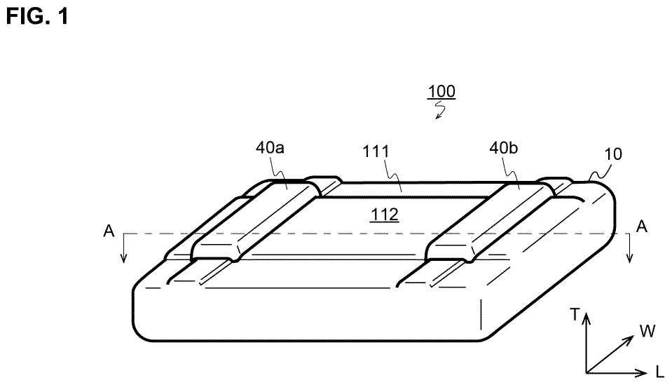

An embodiment of the multilayer ceramic capacitor in the first aspect of the present invention is shown in FIG. 1 to FIG. 3 as a first embodiment. The multilayer ceramic capacitor 100 in the first embodiment has a cuboid shape with a pair of faces each perpendicular to the three axes, namely, an L-axis in the length direction, a W-axis in the width direction, and a T-axis in the height direction, where these axes are orthogonal to each other. The cuboid is not limited to a cuboid as defined mathematically, but includes any shape that is recognizable as a cuboid after observing its overall shape. Therefore, those with edges and corners that are slightly rounded, edges that are slightly curved, and surfaces that are curved surfaces with a small curvature also fall under the category of cuboid in the present disclosure. The length (L), width (W), and height (T) dimensions of the ceramic capacitor 100 can each be set independently to any value.

Examples of dimensions for the multilayer ceramic capacitor 100 are an L-direction dimension of 200 μm or more and 2000 μm or less, a W-direction dimension of 100 μm or more and 2000 μm or less, a T-direction dimension of 30 μm or more and 220 μm or less, and a W/L ratio, or the ratio of the W-direction dimension to the L-direction dimension, of 0.3 or more and 1.0 or less. Each of these dimensions is preferably an L-direction dimension of 400 μm or more and 1200 μm or less, a W-direction dimension of 400 μm or more and 1200 μm or less, a T-direction dimension of 40 μm or more and 150 μm or less, and a W/L ratio, which is the ratio of the W-direction dimension to the L-direction dimension, of 0.4 or more and 1.0 or less. The T-direction dimension is preferably 100 μm or less, as this is less likely to be constrained by the design of the circuit board on which it is mounted.

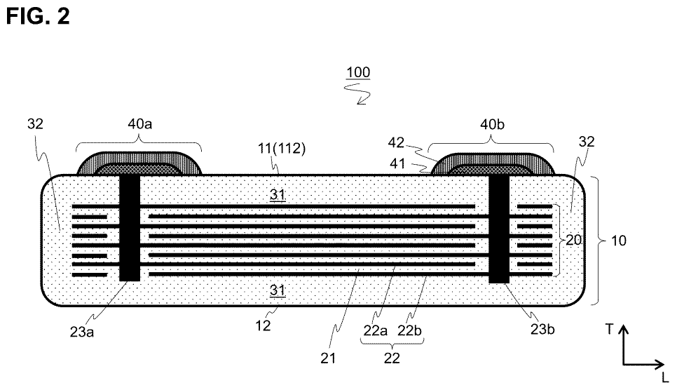

As schematically shown in the cross-sectional view in FIG. 2, the multilayer ceramic capacitor 100 in the first embodiment comprises an element body having a multilayer unit 20 obtained by alternately laminating in the T direction ceramic layers 21 and internal electrodes 22 composed primarily of metal, a pair of covering portions 31 covering surfaces of the multilayer unit 20, and a margin portion 32 connecting the pair of covering portions 31 while covering at least some of the end portions of the ceramic layers 21 and the end portions of the internal electrodes 22 in the multilayer unit 20. The internal electrodes 22 include internal electrodes 22a of one polarity electrically connected to each other, and an internal electrodes 22b of a different polarity from the internal electrode 22a electrically connected to each other.

The method used to electrically connect the internal electrodes 22a to each other and the internal electrodes 22b to each other is not particularly limited. FIG. 2 shows a configuration in which via conductors 23 (23a, 23b) are arranged inside the element body 10 in the laminating direction of the multilayer unit 20, passing through the ceramic layers 21 and having at least one end reaching the surface of a covering portion 31 as described later. However, as shown in the second embodiment described below, the internal electrodes may be extended to the end faces of the element body and be connected via external conductors. Note that the multilayer ceramic capacitor 100 shown in FIG. 2 has two via conductors 23, but the number of via conductors in the multilayer ceramic capacitor in the first aspect of the present invention is not limited to this.

The covering portions 31 are disposed on the surfaces of the element body 10 perpendicular to the T direction of the multilayer unit 20, and the margin portions 32 are disposed on the surfaces perpendicular to the W direction and perpendicular to the L direction of the multilayer unit 20. Note that, as described in the second embodiment below, when the internal electrodes are drawn out to the end faces of the element body, margin portions are not provided on the end faces (draw-out faces) where the internal electrodes are drawn out.

The multilayer ceramic capacitor 100 in the first embodiment comprises a plurality of terminal electrodes 40 (40a, 40b) that are electrically connected to the internal electrodes 22 (22a, 22b) and are arranged apart from each other on the mounting surface 11, which is one of the surfaces forming the surfaces of the element body 10, facing the circuit board when the capacitor is mounted on the circuit board. A plurality of terminal electrodes 40 (40a, 40b) are arranged in m units on the mounting surface 11 in a first direction (L direction) and in n units in a second direction (W direction) perpendicular to the first direction. (Here, m is a natural number equal to or greater than 2 and n is a natural number.) Here, the first direction and the second direction are determined by projecting each terminal electrode 40 (40a, 40b) perpendicularly to the mounting surface 11, and fitting the centroids of each projected figure by the least squares method to obtain straight lines. The method used to electrically connect the terminal electrodes 40 (40a, 440b) and internal electrodes 22 (22a, 22b) is not particularly limited. FIG. 2 shows a configuration in which the electrodes are connected by way of via conductors 23 (23a, 23b), but as described in the second embodiment below, they may also be connected by way of external conductors. Note that the multilayer ceramic capacitor 100 in FIG. 2 has two terminal electrodes 40 corresponding to m=2 and n=1, but the number of terminal electrodes in the multilayer ceramic capacitor in the first aspect of the present invention is not limited to this.

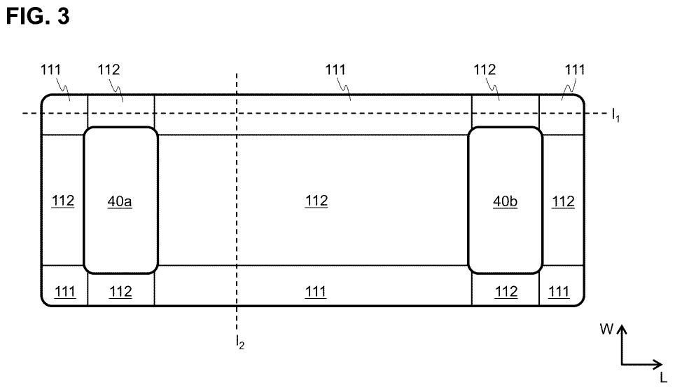

The multilayer ceramic capacitor 100 in the first embodiment, as shown in FIG. 3, a region of the mounting surface 11 of the element body 10 in which terminal electrodes 40 (40a, 40b) are not arranged has mounting surface side intersection portions 111 and mounting surface side non-intersection portions 112. A mounting surface side intersection portion 111 is a portion in which a first straight line l₁ and a second straight line l₂ intersect, when the first straight line l₁ is drawn on the mounting surface 11 to extend without contacting either of the terminal electrodes 40 (40a, 40b) in a first direction (L direction) along which one of the terminal electrodes 40 (40a, 40b) is arranged, and the second straight line l₂ is drawn on the mounting surface to extend without contacting either of terminal electrodes 40 (40a, 40b) in a second direction (W direction), which is the other arrangement direction (the direction perpendicular to the first direction) of the terminal electrodes 40 (40a, 40b). The mounting surface side non-intersection portions 112 are portions in which an intersection point between the first straight line l₁ and the second straight line l₂ is not formed. The element body 10 satisfies T1<T2, where T1 is the dimension of the element body 10 in the laminating direction (T direction) measured with reference to a mounting surface side intersection portion 111, and T2 is the dimension in the T direction measured with reference to a mounting surface side non-intersection portion 112.

The maximum thickness of the element body 10, obtained by subtracting the thickness of the terminal electrodes 40 (40a, 40b) from the T-direction dimension of the multilayer ceramic capacitor 100, is, for example, 20 μm or more and 200 μm or less, and preferably 30 μm or more and 180 μm or less.

Each component constituting the multilayer ceramic capacitor 100 in the first embodiment will now be described in detail.

### (Ceramic Layers)

Ceramic layers 21 are formed of ceramic. The composition of the ceramic is not particularly limited as long as it forms dense ceramic layers 21 when simultaneously fired with the internal electrodes 22 described below, and may be selected based to the characteristics required of the multilayer ceramic capacitor. Examples of ceramic compositions include those composed primarily of barium titanate (BaTiO₃), strontium titanate (SrTiO₃), and Ba_{1-x-y}CaₓSr_{y}Ti_{1-z}Zr₂O₃, which has a perovskite structure. The ceramic may contain additive elements along with the main components mentioned above. Examples of additive elements include at least one selected from Mo, Nb, Ta, W, Mg, Mn, V, Cr, and rare earth elements (Y, Sm, Eu, Gd, Tb, Dy, Ho, Er, Tm, and Yb), and Co, Ni, Li, B, Na, K, and Si. Additive elements may be present as individual elements or in the form of compounds such as oxides, nitrides, and carbides. In addition, the additive elements may be present in a solid solution state along with the primary components, or may form a different phase with the elements constituting the primary components or other additive elements.

### (Internal Electrodes)

The internal electrodes 22 (22a, 22b) are primarily composed of metal. The type of metal is not particularly limited, and examples include nickel (Ni), copper (Cu), palladium (Pd), platinum (Pt), silver (Ag), and gold (Au), as well as alloys of these metals. Among these metals, those containing nickel (Ni) as the primary constituent element are preferable because they can form dense ceramic layers 21 when the firing temperature is raised while firing the ceramic layers 21 due to their high heat resistance, and because they are relatively inexpensive. In the present specification, “primary constituent element” refers to the element with the highest content expressed as atomic percentage (atom %).

The internal electrodes 22 (22a, 22b) may contain, in addition to metal, ceramic particles having the same composition as the ceramic constituting the ceramic layers 21, or glass components.

### (Covering Portions and Margin Portions)

The covering portions 31 and the margin portions 32 both have a function of protecting the ceramic layers 21 and the internal electrodes 22. Materials for the covering portions 31 and the margin portions 32 are not limited as long as they have high electrical insulation properties and low permeability to moisture and other deteriorating factors. In order to uniformly provide shrinkage during firing and relieve internal stress in the multilayer ceramic capacitor 100, the primary component of the covering portions 31 and the margin portions 32 is preferably the same as the ceramic used to form the ceramic layers 21.

### (Via Conductors)

The via conductors 23 (23a, 23b) are composed primarily of metal, similar to the internal electrodes 22 (22a, 22b). The metals that can be used are the same metals as those used in the internal electrodes 22 (22a, 22b) described above. The composition of the via conductors may be different from that of the internal electrodes 22 (22a, 22b), but is preferably the same as that of the internal electrodes 22 (22a, 22b). When the via conductors (23a, 23b) and the internal electrodes 22 (22a, 22b) have the same composition, the amount of shrinkage caused by firing is uniform during production of the multilayer ceramic capacitor 100, thereby suppressing deformation. The resistivity of the conductive paths in the multilayer ceramic capacitor 100 are also uniform, thereby suppressing localized heating during use.

The diameter of the via conductors (23a, 23b) is not particularly limited, but in order to ensure the capacitance of the multilayer ceramic capacitor 100 while reducing electrical resistance and suppressing heat generation during circuit operation, the diameter is preferably 5 μm or more and 100 μm or less, and more preferably 10 μm or more and 50 μm or less.

### (Terminal Electrodes)

The material of the terminal electrodes 40 (40a, 40b) is not limited as long as it is a conductive material. Examples of materials include metals such as nickel (Ni), copper (Cu), tin (Sn), palladium (Pd), platinum (Pt), silver (Ag), and gold (Au), alloys containing any of these as the primary constituent element, and conductive resins.

The terminal electrodes 40 (40a, 40b) may include base conductors 41 in contact with the element body 10 and plated conductors 42 formed on the surface of the base conductors 41. Terminal electrodes 40 (40a, 40b) with this structure improve the bonding strength to the element body 10 by the base conductors 41, while improving solder wettability during circuit board mounting by the plated conductors 42.

An example of a material for the base conductors 41 is Ni. The thickness of the base conductors 41 is, for example, 0.1 μm or more and 10 μm or less, and preferably 0.5 μm or more and 5 μm or less.

The plated conductors 42 may be formed with a single layer or multiple layers. When the plated conductors 42 have multiple layers, they preferably have two to four layers. The material and structure of plated conductors 42 can be a structure formed in the order Cu, Ni, and Sn. The thickness of the plated conductors 42 is, for example, 1 μm or more and 20 μm or less, and preferably 3 μm or more and 10 μm or less.

The area of the terminal electrodes 40 (40a, 40b), that is, the area of the terminal electrodes 40 (40a, 40b) as viewed from the direction perpendicular to the mounting surface 11 of the multilayer ceramic capacitor 100, is not particularly limited, but should be large enough to facilitate mounting of the capacitor on a circuit board, but small enough to prevent short circuits between electrodes with different polarities. Preferably, the ratio of the total area of the terminal electrodes 40 to the area of the mounting surface 11 is 0.2 or more and 0.9 or less, and more preferably, 0.3 or more and 0.8 or less.

### (Mounting Surface of the Element Body)

In the regions in which terminal electrodes 40 (40a, 40b) are not arranged on the mounting surface 11 of element body 10, as described above, there are mounting surface side intersection portions 111 and mounting surface side non-intersection portions 112. Here, T1<T2, where T1 is the dimension in the T direction of the element body 10 as measured with reference to a mounting surface side intersection portion 111, and T2 is the dimension in the T direction of the element body 10 as measured with reference to the mounting surface side non-intersection portion 112. Thus, some of the molten solder flows from the corners of terminal electrodes 40 (40a, 40b) to the mounting surface side intersection portions 111 and solidifies when the multilayer ceramic capacitor 100 is mounted on a circuit board, thereby increasing the contact area with the surface of the element body 10 and/or the terminal electrodes 40 (40a, 40b). As a result, the bonding strength between the multilayer ceramic capacitor 100 and the solder is increased.

T1 and T2 should preferably satisfy 0.1 μm≤(T2-T1)≤10 μm. When the value of (T2-T1) is 0.1 μm or more, solder easily flows into the mounting surface side intersection portion 111 during mounting on a circuit board. From this standpoint, it is more preferable that the value of (T2-T1) be 0.3 μm or more, and it is even more preferable that it be 0.5 μm or more. Meanwhile, because the value of (T2-T1) is 10 μm or less, the thickness of the covering portions 31 and the margin portions 32 can be ensured without increasing the T-direction dimension of the multilayer ceramic capacitor 100, thus effectively suppressing the intrusion of moisture and other deterioration factors into the multilayer unit 20. From this standpoint, it is more preferable that the value of (T2−T1) be 9 μm or less, and even more preferable that it be 8 μm or less. From the above, it is preferable that the value of (T2−T1) satisfy 0.3 μm≤(T2-T1)≤9 μm, and it is even more preferable that it satisfy 0.5 μm≤(T2−T1)≤8 μm.

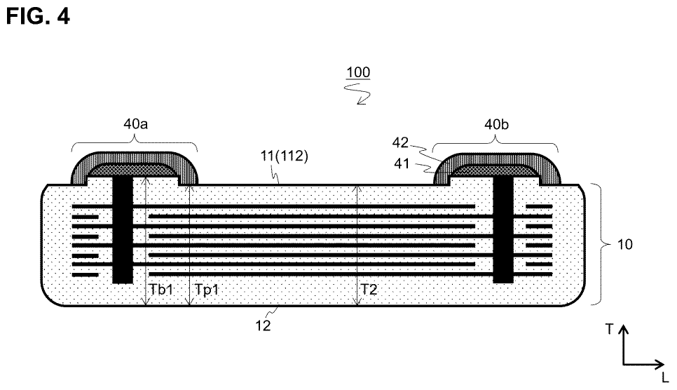

When the terminal electrodes 40 (40a, 40b) have base conductors 41 and plated conductors 42, the element body 10 preferably satisfies T2≤Tp1<Tb1, as shown in FIG. 4, where Tb1 is the dimension in the T direction as measured with reference to a region in which a base conductor 41 is arranged on the mounting surface 11, and Tp1 is the dimension in the T direction as measured with reference to the region in which a plated conductor 42 is in contact with the mounting surface 11. This increases the contact area between the element body 10 and the plated conductors 42, thereby increasing the bonding strength between the two.

The arithmetic mean roughness Ra of the mounting surface side intersection portion 111 is preferably 0.01 μm or more and 1 μm or less. When Ra is 0.01 μm or more, solder flowing from the terminal electrodes 40 (40a, 40b) to the mounting surface side intersection portions 111 during mounting of the multilayer ceramic capacitor 100 on a circuit board is kept from spreading to adjacent terminal electrodes 40 (40a, 40b). Also, when mounting the multilayer ceramic capacitor 100 on a circuit board, filling the spaces between the terminal electrodes 40 (40a, 40b) with resin improves the adhesive strength between the resin and the capacitor. From these standpoints, the Ra is preferably 0.05 μm or more, and more preferably 0.1 μm or more. When the Ra is 1 μm or less, the intrusion of moisture and other deterioration factors into the multilayer unit 20 can be effectively suppressed by ensuring the thickness of the covering portions 31 and the margin portions 32 without increasing the T direction dimension of the multilayer ceramic capacitor 100. From this standpoint, the Ra is preferably 0.9 μm or less, and more preferably 0.8 μm or less. Therefore, the Ra is preferably 0.1 μm or more and 0.9 μm or less, and more preferably 0.15 μm or more and 0.8 μm or less.

Here, determination that T1<T2 and calculation of the arithmetic mean roughness Ra of the mounting surface side intersection portions 111 are performed using a laser microscope. More specifically, the unevenness of the mounting surface 11 of the multilayer ceramic capacitor 100 is measured using a laser microscope, and it is determined that T1<T2 when the average height of the mounting surface side intersection portions 111 is smaller than the average height of the mounting surface side non-intersection portions 112. In addition, the arithmetic mean roughness Ra of the mounted surface side intersection portion 111 is obtained by analyzing the measurement results of the unevenness of the mounting surface side intersection portion 111 using the software that comes with the laser microscope.

T1, T2, Tb1, and Tp1 are calculated using the following procedures. First, in the measurements using the laser microscope described above, the multilayer ceramic capacitor 100 for which T1<T2 is to be determined is cut at two points on the plane passing through the vicinity of the centroid of the terminal electrodes 40 (40a, 40b) as viewed from a direction parallel to the mounting surface 11 and parallel to either the first direction or the second direction in which the terminal electrodes 40 (40a, 40b) are arranged, and on the plane parallel to this plane and passing through the vicinity of the centroid of the mounting surface side intersection portions 111 to expose a cross section including a terminal electrode 40 (40a, 40b) and a cross section including a mounting surface side intersection portion 111. Here, the vicinity of the centroid refers to a region within a distance of w/6 from the centroid, where w is the dimension in the direction perpendicular to each cutting plane at the terminal electrode 40 (40a, 40b) or the mounting surface side intersection portion 111. Note that whether the cutting direction is the first direction or the second direction can basically be selected at will, but the second direction is selected so that a cross section including a mounting surface side intersection portion 111 is easy to expose when n=1, that is, the number of terminal electrodes 40 (40a, 40b) arranged in the second direction is 1, and the distance between the terminal electrode 40 (40a, 40b) and the peripheral edge of the mounting surface 11 is close. Next, a conductive material such as carbon is deposited on each exposed cross section, and the cross sections are observed using a scanning electron microscope (SEM). Next, in the SEM image of the cross section including the mounting surface side intersection portion 111, five points located in the mounting surface side intersection portion 111 are selected, the distance from each point to the opposite surface 12 is measured, and the average value is calculated. Then, the calculated average value is divided by the SEM magnification factor to obtain T1. Next, in the SEM image of the cross section including the mounting surface side intersection portion 111, five points located in the mounting surface side non-intersection portion 112 are selected, the distance from each point to the opposite surface 12 is measured, and the average value is calculated. Then, the calculated average value is divided by the SEM magnification factor to obtain T2. Next, in the SEM image of the cross section including the terminal electrode 40 (40a, 40b), five points located at the boundary between the base conductor 41 and the element body 10 are selected, the distance from each point to the opposite surface 12 is measured, and the average value is calculated. Then, the calculated average value is divided by the SEM magnification factor to obtain Tb1. Next, in the SEM image of the cross section including the terminal electrode 40 (40a, 40b), five points located at the boundary between the plated conductor 42 and the element body 10 are selected, the distance from each point to the opposite surface 12 is measured, and the average value is calculated. Then, the calculated average value is divided by the SEM magnification factor to obtain Tp1.

### Second Embodiment

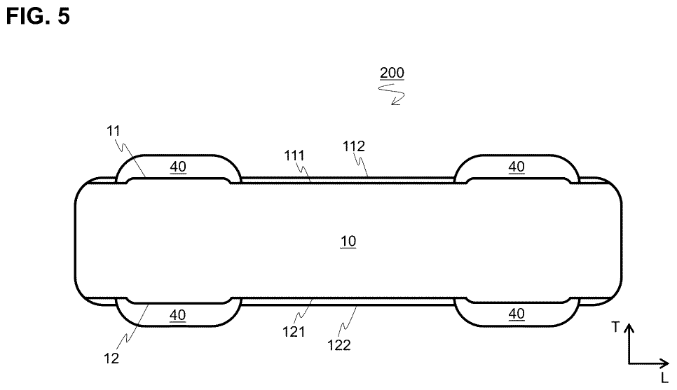

Another embodiment (second embodiment) of the multilayer ceramic capacitor in the first aspect of the present invention also has terminal electrodes arranged on the opposite surface facing the mounting surface of the element body. An example of the multilayer ceramic capacitor 200 in the second embodiment is shown in FIG. 5. In this multilayer ceramic capacitor 200, terminal electrodes 40 are arranged in p units in the third direction (L direction) on the opposite surface 12 and terminal electrodes 40 are arranged in q units in the fourth direction (W direction) perpendicular to the third direction in a grid pattern (where p is a natural number equal to or greater than 2 and q is a natural number), and opposite surface side intersection portions 121 and opposite surface side non-intersection portions 122 that have a greater height than the opposite surface side intersection portions 121 are provided in regions in which terminal electrodes 40 are not arranged. The opposite surface side intersection portions 121 are portions in which a third straight line and a fourth straight line intersect, when the third straight line is drawn on the opposite surface 12 to extend in the third direction (L direction) without touching any of the terminal electrodes 40 and the fourth straight line, which is the other arrangement direction for the terminal electrodes 40 (the direction perpendicular to the third direction) is drawn on the opposite surface to extend in the fourth direction (W direction) without touching any of the terminal electrodes 40. Meanwhile, the non-intersection portions 122 on the opposite surface side are portions in which the third straight line and the fourth straight line do not intersect. The relative positions of the opposite surface side intersection portions 121 and the opposite surface side non-intersection portions 122, as well as the third straight line and the fourth straight line, can be understood, using FIG. 3, by replacing the mounting surface side intersection portions 111 with the opposite surface side intersection portions 121, the mounting surface side non-intersection portions 112 with the opposite surface side non-intersection portions 122, the first straight line l₁ with the third straight line, and the second straight line 12 with the fourth straight line, respectively. Also, the height of the opposite surface side non-intersection portion 122 is greater than that of the opposite surface side intersection portion 121, and T3<T4, where T3 is the dimension of the element body 10 in the T direction as measured with reference to an opposite surface side surface intersection portion 111, and T4 is the dimension of the element body 10 in the T direction as measured with reference to an opposite surface side non-intersection portion 122. Note that p=2 and q=1 in multilayer ceramic capacitor 200, but the number of terminal electrodes arranged on the opposite surface of the multilayer ceramic capacitor in the second embodiment is not limited to this. The multilayer ceramic capacitor 200 has convex portions formed by the terminal electrodes 40 and concave portions present in the opposite surface side intersection portions 121, which makes the opposite surface 12 uneven. This reduces the contact area with other components and elements, thereby suppressing the amount of static electricity generated during handling.

For the same reasons as T1 and T2 explained above, T3 and T4 should satisfy 0.1 μm≤(T4−T3)≤10 μm, more preferably 0.3 μm≤(T4−T3)≤9 μm, and even more preferably 0.5 μm≤(T4−T3)≤8 μm.

When the terminal electrodes 40 arranged on the opposite surface 12 have base conductors 41 and plated conductors 42, for the same reasons as Tb1 and Tp1 mentioned above, the multilayer ceramic capacitor 200 satisfies T4≤Tp2<Tb2, where Tb2 is the dimension of the element body 10 in the T direction as measured with reference to the region in which a base conductor 41 is arranged on the opposite surface 12, and Tp2 is the dimension of the element body 10 in the T direction, as measured with reference to a region in which a plated conductor 42 contacts the opposite surface 12.

The arithmetic mean roughness Ra of the opposite surface side intersection portion 121 is preferably 0.05 μm or more and 1 μm or less. When Ra is 0.05 μm or more, the amount of static electricity generated when handling the multilayer ceramic capacitor 100 can be effectively suppressed. From this standpoint of view, Ra is preferably 0.1 μm or more, and more preferably 0.15 μm or more. When the Ra is 1 μm or less, the intrusion of moisture and other deterioration factors into the multilayer unit 20 can be effectively suppressed by ensuring the thickness of the covering portions 31 and the margin portions 32 without increasing the T direction dimension of the multilayer ceramic capacitor 100. From this standpoint, the Ra is preferably 0.9 μm or less, and more preferably 0.8 μm or less. Therefore, the Ra is preferably 0.1 μm or more and 0.9 μm or less, and more preferably 0.15 μm or more and 0.8 μm or less.

Here, determination that T3<T4 and calculation of the arithmetic mean roughness Ra of the opposite surface side intersection portions 121 are performed by applying to the opposite surface 12 the steps described above for determining whether T1<T2 and calculating the arithmetic mean roughness Ra of the mounting surface side intersection portion 111. Also, T3, T4, Tb2, and Tp2 are calculated by replacing the mounting surface 11 with the opposite surface 12 in the procedure used to calculate T1, T2, Tb1, and Tp1 as described above.

### Third Embodiment

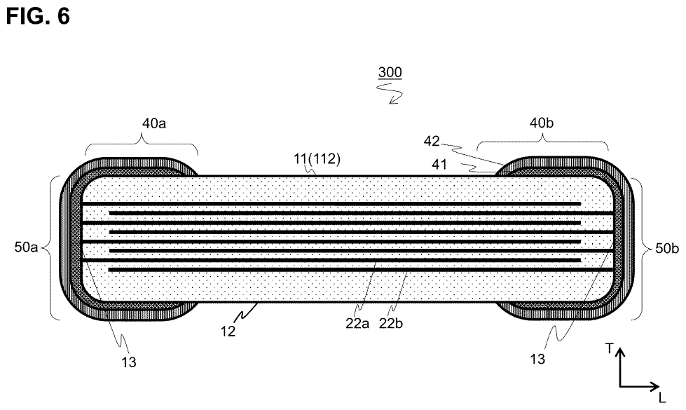

Another embodiment (third embodiment) of the multilayer ceramic capacitor in the first aspect of the present invention has electrical connections between the internal electrodes established using external conductors. An example of a multilayer ceramic capacitor 300 in the third embodiment is shown in FIG. 6. In the multilayer ceramic capacitor 300, the internal electrodes 22 (22a, 22b) drawn out to the draw-out surfaces 13 of the element body 10 are electrically connected to each other by external conductors 50 (50a, 50b), and the external conductors 50 (50a, 50b) are electrically connected to the terminal electrodes 40 (40a, 40b) arranged on the mounting surface 11. Note that the multilayer ceramic capacitor 300 has a pair of end faces formed so that the external conductors 50 (50a, 50b) oppose each other, but a multilayer ceramic capacitor in the third embodiment may have an external conductor formed on only one end surface, or on the draw-out surface 13 without going around the opposite surface 12.

### Fourth Embodiment

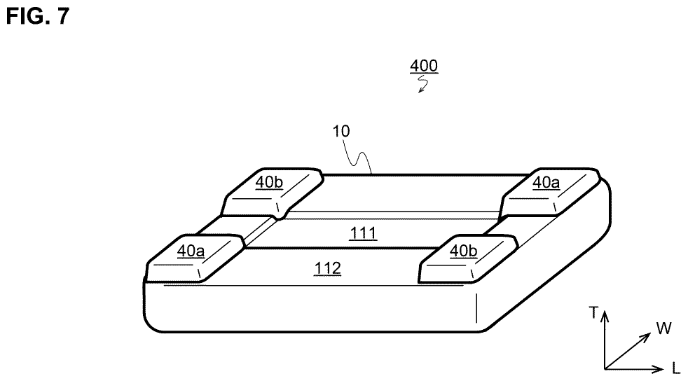

Another embodiment (the fourth embodiment) of the multilayer ceramic capacitor in the first aspect of the present invention has, on the mounting surface, terminal electrodes arranged in m units in the first direction and terminal electrodes arranged in n units in the second direction, both of which are equal to or greater than 2. Therefore, the total number of terminal electrodes located on the mounting surface is four or more. An example of the multilayer ceramic capacitor 400 in the fourth embodiment is shown in FIG. 7. Note that while the number of terminal electrodes 40 arranged on the mounting surface 11 of multilayer ceramic capacitor 400 is four, the number of terminal electrodes arranged on the mounting surface is not limited to this. The multilayer ceramic capacitor 400 has the advantage of reducing resistive heating because it can suppress the amount of current flowing through the via conductors 23 (23a, 23b) electrically connected to each terminal electrode 40 (40a, 40b). Also, when the polarities of the terminal electrodes 40 (40a, 40b) that are closest to each other on the mounting surface are different, the directions in which the current flows through the via conductors 23 (23a, 23b) electrically connected to each terminal electrode 40 (40a, 40b) are opposite to each other between the closest via conductors 23 (23a, 23b). Therefore, the magnetic fields generated by the current cancel each other out, which has the advantage of reducing the equivalent series inductance (ESL). The ESL reducing effect is significant when the mounting surface 11 of the multilayer ceramic capacitor 400 has a shape close to a square, that is, when the ratio of W to L, that is, W/L, is 0.8 or greater and 1 or less, where among the two opposite surfaces parallel to the laminating direction of the multilayer unit, the distance in one direction, that is, the L-direction dimension, is L μm, and the distance in the other direction, that is, the W-direction dimension, is W μm (where L≥W).

### Method for Manufacturing Multilayer Ceramic Capacitor

The multilayer ceramic capacitor in the first aspect of the present invention can be manufactured by the following procedures.

### Preparation of Ceramic Powder (A)

First, the ceramic powder is prepared. Commercially available ceramic powder can be used when appropriate. When preparing the ceramic powder, the raw material powders containing the constituent elements may be mixed together at the specified ratios and preliminary firing (pre-firing) performed. When mixing the raw material powders together at the predetermined ratios, additives such as the additive elements listed above and sintering aids may be added. However, these additives may also be added to the powder after pre-firing.

### Preparation of Green Sheets (B)

Next, the ceramic powder is mixed with a binder and a dispersing medium to prepare a slurry, and the slurry is formed into a sheet to obtain a green sheet.

The binder can be any one that can maintain the shape of the green sheet and, during binder removal processing prior to firing, allows volatile substances to evaporate without leaving carbon or other residues. Examples of binders that can be used include polyvinyl alcohol-based, polyvinyl butyral-based, cellulose-based, urethane-based, and vinyl acetate-based binders. The amount of binder used is not particularly limited, but since it is to be removed in a subsequent step, it is preferable to use as little as possible within a range that allows the desired moldability and shape retention to be obtained and that also reduces raw material costs.

The dispersing medium can be one that does not cause agglomeration of the pre-fired powder and the biner and that can be easily removed by volatilization, etc., after green sheet molding described below. Examples of dispersing media that can be used include water and alcohol-based solvents.

The slurry may contain components such as dispersants, plasticizers, and thickeners to adjust the properties of the slurry.

The method used to mix the mixed powder with a binder and a dispersing medium is not particularly limited as long as it prevents the introduction of impurities and ensures that each component is uniformly mixed. One example is ball mill mixing.

Methods that can be used to form the prepared slurry into a sheet to obtain a green sheet include conventional methods such as the doctor blade method and the die coating method.

### Formation of Internal Electrode Patterns (C)

Next, an internal electrode pattern containing metal is formed on the green sheet. The internal electrode pattern can be formed by printing or coating an internal electrode paste in a predetermined pattern, or by forming a metal film in a predetermined pattern by vapor deposition or sputtering deposition. The internal electrode pattern is formed with sufficient margin to ensure electrical insulation from the via conductor pattern formed later, with which it is not to make contact.

When forming an internal electrode pattern using internal electrode paste, the internal electrode paste used is obtained by mixing metal particles into a vehicle using a three-roll mill. The internal electrode paste may also contain glass frit or ceramic powder in addition to these components.

The types and amounts of binders and solvents included in the vehicle to be used are not limited, but should be selected after taking into consideration the viscosity of the internal electrode paste, ease of handling, and compatibility with the green sheet.

Printing of the internal electrode paste on the green sheet can be performed, for example, using a screen mask with a predetermined internal electrode pattern formed upon it. When printing, a space is left for the margins when used as a multilayer ceramic capacitor.

### Preparation of Green Multilayer Unit (D)

Next, a predetermined number of green sheets with internal electrode patterns formed on them are laminated, and the green sheets are bonded together by pressing to obtain a green multilayer unit. The laminating and bonding can be performed using conventional methods. For example, pressing the laminated green sheets together in the laminating direction while heating, and then heat-bonding them together by the action of the binder. At this time, a mold with convex portions on its surface may be pressed against the green sheet to form recessed portions in the regions that are to become the mounting surface side intersection portions.

When laminating and bonding, a green sheet may be added to the end portions in the laminating direction to serve as covering portions once the multilayer ceramic capacitor is formed. In this case, the added green sheets may have the same composition as the green sheets on which the internal electrode pattern is printed, or may have a different composition. From the standpoint of ensuring uniform shrinkage during firing, the composition of the added green sheets is preferably the same or similar to that of the green sheets in which the internal electrode precursors have been arranged.

### Formation of Via Conductors (E)

When manufacturing a multilayer ceramic capacitor in the first embodiment, holes are formed in the green multilayer unit, and a conductor paste is added to fill the holes and form a via conductor pattern. Conventional methods such as drilling and laser cutting can be used to form the holes. Among these, laser cutting is preferred because it produces smooth machined surfaces. Conventional methods such as injection using a syringe or printing using a metal mask can be used to add the conductive paste to fill the holes. Among these, printing using a metal mask is preferred due to its excellent filling properties for small holes. The same components as those used for the internal electrode paste described above can be used for the conductive paste, and the proportions of each component can be determined based on the filling properties for the holes.

### Formation of Terminal Electrode Pattern (F)

Next, a terminal electrode pattern is formed on at least one of the surfaces perpendicular to the laminating direction of the green multilayer unit (the mounting surface). At this time, a green sheet that will become the covering portion once the multilayer ceramic capacitor is formed can be applied so that it covers the via conductor pattern on the surface where the terminal electrode pattern is not formed. The terminal electrode pattern can be formed by printing or coating terminal electrode paste, or by forming metal film by vapor deposition or sputtering deposition. At this time, the terminal electrode pattern may be formed using a mask with a predetermined pattern, or a paste film or metal film may be formed over the entire mounting surface of the green multilayer unit and the portions other than the terminal electrode pattern removed to form a pattern. Surface milling, barrel grinding, etc. can be used to remove parts other than the terminal electrode pattern. When removing the portions other than the terminal electrode pattern, removing portions of the surface of the green multilayer unit also allows recessed portions to be formed at positions corresponding to the mounting surface side intersection portions. When using terminal electrode paste to form a terminal electrode pattern, the same components as those used for the internal electrode paste described above can be used, and the proportions of each component can be determined so that a uniform pattern of a specified thickness can be obtained.

### Preparation of Pre-Fired Chips (G)

Next, the green multilayer unit is divided into individual laminated ceramic capacitor shapes through a process called “chipping” to obtain pre-fired chips. Chipping can be performed using conventional methods with a dicing saw or a laser cutting machine. After separating the green multilayer unit into individual units and forming a surface exposing the internal electrode precursors, the surface may be coated with a material for forming the margin portions to obtain pre-fired chips.

### Removal of Binder (H)

Next, the pre-fired chips are heated to volatilize and remove the binder. The heating conditions can be set after taking into consideration the volatilization temperature and content of the binder. In one example, the temperature is held at 200° C. to 500° C. for 5 to 20 hours in a nitrogen (N₂) atmosphere.

### Firing of Pre-Fired Chip (I)

Next, the pre-fired chips with the binder removed are heated to a specified temperature and fired. When setting the firing conditions, the firing properties of the ceramic powder and the heat resistance and oxidation resistance of the metals contained in the internal electrode pattern, via conductor pattern, and terminal electrode pattern should be taken into consideration. In one example of firing conditions, the temperature is held at 1100° C. to 1400° C. for 10 minutes to 2 hours in a reducing atmosphere that is a mixture of nitrogen (N₂), hydrogen (H₂), and water vapor (H₂O). After firing, a re-oxidation treatment is optionally performed by holding the temperature at 600° C. to 1000° C. in a nitrogen (N₂) gas atmosphere or a low-oxygen atmosphere.

### Formation of External Conductors and Terminal Electrodes (J)

When manufacturing a multilayer ceramic capacitor in the second embodiment, operation (E) above is omitted, and external conductors are formed by following operation (I), or operations (E) and (F) are omitted, and external conductors and terminal electrodes are formed by following operation (I). The method used to form the external conductors and terminal electrodes include applying conductive paste by printing or dipping before baking, or forming metal film by physical vapor deposition (PVD) such as vapor deposition.

The fired body obtained in this manner can be used as a multilayer ceramic capacitor as is, or a conductive layer can be formed on the surface of the terminal electrode pattern by plating before using the fired body as a multilayer ceramic capacitor.

### Circuit Board

The circuit board in the second aspect of the present invention is provided with a multilayer ceramic capacitor according to the first aspect. This circuit board has improved bonding strength of the multilayer ceramic capacitor, thereby providing excellent durability.

The following technologies are also disclosed in the present specification.

### (Addendum 1)

A multilayer ceramic capacitor comprising:
a cuboid element body having
   a multilayer unit alternately laminating ceramic layers and internal electrodes composed primarily of metal,
   a pair of covering portions arranged at both ends of the multilayer unit in the laminating direction and covering surfaces of the multilayer unit, and
   margin portions covering at least some of the end portions of the ceramic layers and the internal electrodes in the multilayer unit, and connecting the pair of covering portions to each other; and
a plurality of terminal electrodes electrically connected to the internal electrodes, and arranged in a spaced-apart manner on a mounting surface, which is one of the surfaces forming the surfaces of the element body, facing the circuit board during circuit board mounting,
wherein
   the plurality of terminal electrodes are arranged in m units in a first direction on the mounting surface and n units in a second direction perpendicular to the first direction (where m is a natural number equal to or greater than 2 and n is a natural number),
   a region in which the terminal electrodes are not arranged on the mounting surface has a mounting surface side intersection portion in which a first straight line and a second straight line intersect, and a mounting surface side non-intersection portion in which the first straight line and the second straight line do not intersect, when the first straight line is drawn to extend in the first direction without touching any of the terminal electrodes and the second straight line is drawn to extend in the second direction without touching any of the terminal electrodes, and
   the element body satisfies T1<T2, where T1 is a dimension in the laminating direction of the element body, as measured with reference to a mounting surface side intersection portion, and T2 is a dimension in the laminating direction of the element body, as measured with reference to a mounting surface side non-intersection portion.

### (Addendum 2)

The multilayer ceramic capacitor according to (Addendum 1), wherein T1 and T2 satisfy

0.1 μm≤(T2−T1)≤10 μm.

### (Addendum 3)

The multilayer ceramic capacitor according to (Addendum 1) or (Addendum 2), wherein the terminal electrodes have a base conductor that contacts the element body and a plated conductor formed on the surface of the base conductor, and the element body satisfies

T2≤Tp1<Tb1,
where Tb1 is a dimension of the element body in the laminating direction, as measured with reference to a region in which a base conductor is arranged on the mounting surface, and Tp1 is a dimension of the element body in the laminating direction, as measured with reference to a region in contact with a plated conductor on a mounting surface.

### (Addendum 4)

The multilayer ceramic capacitor according to any one of (Addendum 1) to (Addendum 3), wherein the arithmetic mean roughness Ra of the mounting surface side intersection portions is 0.05 μm or more and 1 μm or less.

### (Addendum 5)

The multilayer ceramic capacitor according to any one of (Addendum 1) to (addendum 4), wherein
the element body further comprises a plurality of terminal electrodes electrically connected to the internal electrodes, and arranged in a grid pattern on the opposite surface opposing the mounting surface,
the terminal electrodes on the opposite surface are arranged in p units in the third direction (L direction) on the opposite surface and q units in a fourth direction perpendicular to the third direction (where p is a natural number equal to or greater than 2 and q is a natural number),
a region in which the terminal electrodes are not arranged on the opposite surface has an opposite surface side intersection portion in which a third straight line and a fourth straight line intersect, and an opposite surface side non-intersection portion in which the third straight line and the fourth straight line do not intersect, when the third straight line is drawn to extend in the third direction without touching any of the terminal electrodes and the fourth straight line is drawn to extend in the fourth direction without touching any of the terminal electrodes, and
the element body satisfies

T3<T4,
where T3 is a dimension in the laminating direction of the element body, as measured with reference to an opposite surface side intersection portion, and T4 is a dimension in the laminating direction of the element body, as measured with reference to an opposite surface side non-intersection portion.

### (Addendum 6)

The multilayer ceramic capacitor according to any one of (Addendum 1) to (Addendum 5), wherein n is a natural number equal to or greater than 2.

### (Addendum 7)

The multilayer ceramic capacitor according to (Addendum 6), wherein the polarity of each terminal electrode is different from that of the other terminal electrodes closest thereto on the mounting surface.

### (Addendum 8)

A circuit board carrying the multilayer ceramic capacitor according to any one of (Addendum 1) to (Addendum 7).

### INDUSTRIAL APPLICABILITY

The present invention is able to provide a multilayer ceramic capacitor with improved bonding strength to a circuit board, and a circuit board on which this multilayer ceramic capacitor is mounted. As a result, the present invention is useful in that it provides a circuit board with excellent durability.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A multilayer ceramic capacitor comprising:
a cuboid element body having
a multilayer unit alternately laminating ceramic layers and internal electrodes composed primarily of metal,
a pair of covering portions arranged at both ends of the multilayer unit in the laminating direction and covering surfaces of the multilayer unit, and
margin portions covering at least some of the end portions of the ceramic layers and the internal electrodes in the multilayer unit, and connecting the pair of covering portions to each other; and
a plurality of terminal electrodes electrically connected to the internal electrodes, and arranged in a spaced-apart manner on a mounting surface, which is one of the surfaces forming the surfaces of the element body, facing the circuit board during circuit board mounting,
wherein
the plurality of terminal electrodes are arranged in m units in a first direction on the mounting surface and n units in a second direction perpendicular to the first direction (where m is a natural number equal to or greater than 2 and n is a natural number),
a region in which the terminal electrodes are not arranged on the mounting surface has a mounting surface side intersection portion in which a first straight line and a second straight line intersect, and a mounting surface side non-intersection portion in which the first straight line and the second straight line do not intersect, when the first straight line is drawn to extend in the first direction without touching any of the terminal electrodes and the second straight line is drawn to extend in the second direction without touching any of the terminal electrodes, and
the element body satisfies T1<T2, where T1 is a dimension in the laminating direction of the element body, as measured with reference to a mounting surface side intersection portion, and T2 is a dimension in the laminating direction of the element body, as measured with reference to a mounting surface side non-intersection portion.

2. The multilayer ceramic capacitor according to claim 1, wherein T1 and T2 satisfy
0.1 μm≤(T2−T1)≤10 μm.

3. The multilayer ceramic capacitor according to claim 1, wherein the terminal electrodes have a base conductor that contacts the element body and a plated conductor formed on the surface of the base conductor, and the element body satisfies
T2≤Tp1<Tb1,
where Tb1 is a dimension of the element body in the laminating direction, as measured with reference to a region in which a base conductor is arranged on the mounting surface, and Tp1 is a dimension of the element body in the laminating direction, as measured with reference to a region in contact with a plated conductor on a mounting surface.

4. The multilayer ceramic capacitor according to claim 1, wherein the arithmetic mean roughness Ra of the mounting surface side intersection portions is 0.01 μm or more and 1 μm or less.

5. The multilayer ceramic capacitor according to claim 1,
wherein
the element body further comprises a plurality of terminal electrodes electrically connected to the internal electrodes, and arranged in a grid pattern on the opposite surface opposing the mounting surface,
the terminal electrodes on the opposite surface are arranged in p units in a third direction (L direction) on the opposite surface and q units in a fourth direction perpendicular to the third direction (where p is a natural number equal to or greater than 2 and q is a natural number),
a region in which the terminal electrodes are not arranged on the opposite surface has an opposite surface side intersection portion in which a third straight line and a fourth straight line intersect, and an opposite surface side non-intersection portion in which the third straight line and the fourth straight line do not intersect, when the third straight line is drawn to extend in the third direction without touching any of the terminal electrodes and the fourth straight line is drawn to extend in the fourth direction without touching any of the terminal electrodes, and
the element body satisfies
T3<T4,
where T3 is a dimension in the laminating direction of the element body, as measured with reference to an opposite surface side intersection portion, and T4 is a dimension in the laminating direction of the element body, as measured with reference to an opposite surface side non-intersection portion.

6. The multilayer ceramic capacitor according to claim 1, wherein n is a natural number equal to or greater than 2.

7. The multilayer ceramic capacitor according to claim 6, wherein the polarity of each terminal electrode is different from that of the other terminal electrodes closest thereto on the mounting surface.

8. A circuit board carrying the multilayer ceramic capacitor according to claim 1.
